(19) United States
(12) Patent Application Publication
(10) Pub. No.: US 2014/0011038 A1
(43) Pub. Date: Jan. 9, 2014

(54) COATING SYSTEM FOR A GAS TURBINE COMPONENT

(71) Applicants: Rupak DAS, Greenville, SC (US); Jon Conrad SCHAEFFER, Simpsonville, SC (US); James ZHANG, Greenville, SC (US)

(72) Inventors: Rupak DAS, Greenville, SC (US); Jon Conrad SCHAEFFER, Simpsonville, SC (US); James ZHANG, Greenville, SC (US)

(73) Assignee: GENERAL ELECTRIC COMPANY, Schenectady, NY (US)

(21) Appl. No.: 13/542,184

(22) Filed: Jul. 5, 2012

(51) Int. Cl. B32B 9/04; C23C 16/48; C23C 4/12; B05D 3/02; C23C 16/44

(52) U.S. Cl. 428/448; 427/344; 427/248.1; 427/446; 427/586

(57) ABSTRACT

A system or method for applying a protective environmental coating for a gas turbine component. The coating includes a bond layer applied to a substrate comprised of a ceramic matrix composite material and environmental barrier coating layers. The first environmental barrier coating layer is bonded to the substrate by the bond layer. The bond layer comprises silicon and particles consisting of particles of Lanthanum or Cerium.

### FIELD OF THE INVENTION

The application generally relates to a composition for protection of an environmental barrier coating (EBC) on ceramic matrix composition substrates. The application relates more specifically to a compositional coating for protection of EBC on a substrate formed of ceramic matrix composites (CMC).

### BACKGROUND OF THE INVENTION

Power generation systems, such as gas turbine engines, steam turbines, and other turbine assemblies include a compressor section for supplying a flow of compressed combustion air, a combustor section for burning fuel in the compressed combustion air, and a turbine section for extracting thermal energy from the combustion air and converting that energy into mechanical energy in the form of a rotating shaft.

Modern high efficiency combustion turbines have firing temperatures that exceed about 1,000° C., and even higher firing temperatures are expected as the demand for more efficient engines continues. Many components that form the “hot gas path” combustor and turbine sections are directly exposed to aggressive hot combustion gases, for example, the combustor liner, the transition duct between the combustion and turbine sections, and the turbine stationary vanes and rotating blades and surrounding ring segments. In addition to thermal stresses, these and other components are also exposed to mechanical stresses, loads, and erosion from particles in the hot gases that further wear on the components.

Many of the cobalt and nickel based superalloy materials traditionally used to fabricate the majority of combustion turbine components used in the hot gas path section of the combustion turbine engine are insulated from the hot gas flow by coating the components with a thermal barrier coating (TBC) in order to survive long term operation in this aggressive high temperature combustion environment.

TBC systems often consist of four layers: the metal substrate, metallic bond coat, thermally grown oxide, and ceramic topcoat. The ceramic topcoat is typically composed of yttria-stabilized zirconia (YSZ), which is desirable for having very low thermal conductivity while remaining stable at nominal operating temperatures typically seen in applications. TBCs experience degradation through various degradation modes that include mechanical rumpling of bond coat during thermal cyclic exposure, accelerated oxidation, hot corrosion, and molten deposit degradation. Even newer ceramics that are under development for thermal barrier applications, such as gadolinia stabilized zirconia, neodymia stabilized zirconia, dysprosia stabilized zirconia also experience similar degradation modes including mechanical rumpling of bond coat during thermal cyclic exposure, accelerated oxidation, hot corrosion, and molten deposit degradation. With the loss of the TBC, the component experiences much higher temperatures and the component life is reduced dramatically.

Many of the ceramic matrix composites (CMC), such as silicon-containing (SiC) or silicon nitride (Si₃N₄) substrate materials, being fabricated for use as combustion turbine components in the hot gas path section of the combustion turbine engine are protected from harmful exposure to chemical environments in the hot gas flow by coating the components with a environmental barrier coating (EBC) in order to survive long term operation in this aggressive high temperature combustion environment.

EBC systems can consist of rare earth (RE) disilicates or rare earth monosilicates, where RE=La, Ce, Pr, Nd, Sm, Eu, Gd, Th, Dy, Ho, Er, Tm, Yb, and Lu, and includes the rare earth-like elements Y and Sc. RE disilicates have a general composition of RE₂Si₂O₇, and RE monosilicates have a general composition of RE₂SiO₅ A drawback of the rare earth disilicate EBCs is that they are vulnerable to leaching of SiO₂ which creates a microporous microstructure in the EBC, and an initially dense EBC is converted to a porous layer in less than the required design lifetime. Thus, such disilicates may not have the durability required for the application. Rare earth monosilicates typically have CTEs that are not well matched to the CTE of the CMC substrate material. As a result, the monosilicate topcoats tend to crack during application, heat treatment and/or service exposure, allowing water vapor to penetrate the topcoat and cause subsurface chemical reactions and/or premature EBC spallation.

Existing solutions for protecting the EBC suggest pumping the Silicon(Si) metal in the inlet of the hot gas path of the turbine to deposit a Silicon Dioxide (SiO₂) thin film on the EBC system. Prior solutions failed to take into account the directional deposition of Si for improved adhesion and greater oxidation protection. The strategic deposition of Si on ceramic matrix composition substrates requires less silicon to produce better adhesion and protection results than is found in the prior art.

Intended advantages of the disclosed systems and/or methods satisfy one or more of these needs or provide other advantageous features. Other features and advantages will be made apparent from the present specification. The teachings disclosed extend to those embodiments that fall within the scope of the claims, regardless of whether they accomplish one or more of the aforementioned needs.

### BRIEF DESCRIPTION OF THE INVENTION

Certain embodiments commensurate in scope with the originally claimed invention are summarized below. These embodiments are not intended to limit the scope of the claimed invention, but rather these embodiments are intended only to provide a brief summary of possible forms of the invention. Indeed, the invention may encompass a variety of forms that may be similar to or different from the embodiments set forth below.

The present invention is based on a composition provided for intrinsic protection of environmental barrier coating (EBC) applied to a ceramic matrix composite (CMC) substrate, e.g., gas turbine blades, during repetitive thermal cycling. The EBC coating by itself is a multilayered structure, protecting (preventing) the underlying CMC from attacks from environmental objects such as hot gas, FOD/DOD, water vapor and dry/wet oxygen. In the conventional EBC systems, the Si-based bond coat between the substrate and protective layers creeps during operations at elevated temperatures due to growth of thermally grown oxide (TGO) layers. This invention discloses a composition configured to stabilize the glassy phase during thermal cycles and to resist devitrification of the glass. In order to deposit the new compositional structure, the nano-coating of silicon metal (Si) and certain compounds will be co-deposited by various methods including directional epitaxy, atmospheric plasma spraying (APS), chemical vapor deposition (CVD), Electron Beam Physical Vapor Deposition (EBPVD) or slurry methods.

One embodiment relates to a coating system for a gas turbine component. The coating system includes a bond layer applied to a substrate comprised of a ceramic matrix composite material; and at least one environmental barrier coating layer; wherein the at least one environmental barrier coating layer is bonded to the substrate by the bond layer; wherein the bond layer comprises silicon and particles consisting of particles of Lanthanum or Cerium.

Another embodiment relates to a method for protecting an environmental barrier coating (EBC) applied to a ceramic matrix composite (CMC) substrate of a turbine engine component. The method includes providing at least one EBC layer, a CMC substrate and a Si-based bond coat; bonding the at least one EBC layer to the CMC substrate via the bond coat; exposing the component to elevated temperature; oxidizing the Si-based bond coat and melting the Si-based bond coat when the component is exposed to the elevated temperature; forming a thermally grown oxide (TGO) as a viscous fluid layer which moves under shear stress originated by a centrifugal load applied to the component; preventing encroachment of water vapor and oxygen species inside an outer-most cracked EBC layer; and prolonging the permeation of the water vapor and oxygen species into the at least one EBC layer and towards CMC substrate.

The disclosed coating system provides protection to the EBC system by increasing the useful life of CMC blades.

Another advantage is to increase the life of CMC turbine blades by preventing dry/wet oxygen and water vapor from penetrating inside the EBC layers.

Still another advantage is the ability to extend the useful life of CMC blades without changing the chemical or materials composition.

Yet another advantage includes cost saving resulting from the use of less expensive materials, easier implementation with current coating technology, greater reliability and longer useful life of CMC buckets and the associated gas turbine engine.

### BRIEF DESCRIPTION OF THE DRAWINGS

FIG. 1 shows an exemplary power generation system.

FIG. 2 shows an exemplary coating system applied to CMC substrate.

FIG. 3 is a graph illustrating the rate of creep of a thermally grown oxide layer.

FIG. 4 shows an exemplary power generation system component with the compositional bond coat represented in FIG. 2.

FIG. 5 shows an EBC layer bonded to a CMC substrate via a Si-based bond coat.

### DETAILED DESCRIPTION OF THE INVENTION

One or more specific embodiments of the present invention will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present invention, the articles “a,” “an,” “the,” and “said” are intended to mean that there are one or more of the elements. The terms “comprising,” “including,” and “having” are intended to be inclusive and mean that there may be additional elements other than the listed elements.

Power generation systems include, but are not limited to, gas turbines, steam turbines, and other turbine assemblies. In certain applications, power generation systems, including the turbomachinery therein (e.g., turbines, compressors, and pumps) and other machinery may include components that are exposed to heavy wear conditions. For example, certain power generation system components such as blades, casings, rotor wheels, shafts, nozzles, and so forth, may operate in high heat and high revolution environments. As a result of the extreme environmental operating conditions thermal and environmental barrier coatings are needed.

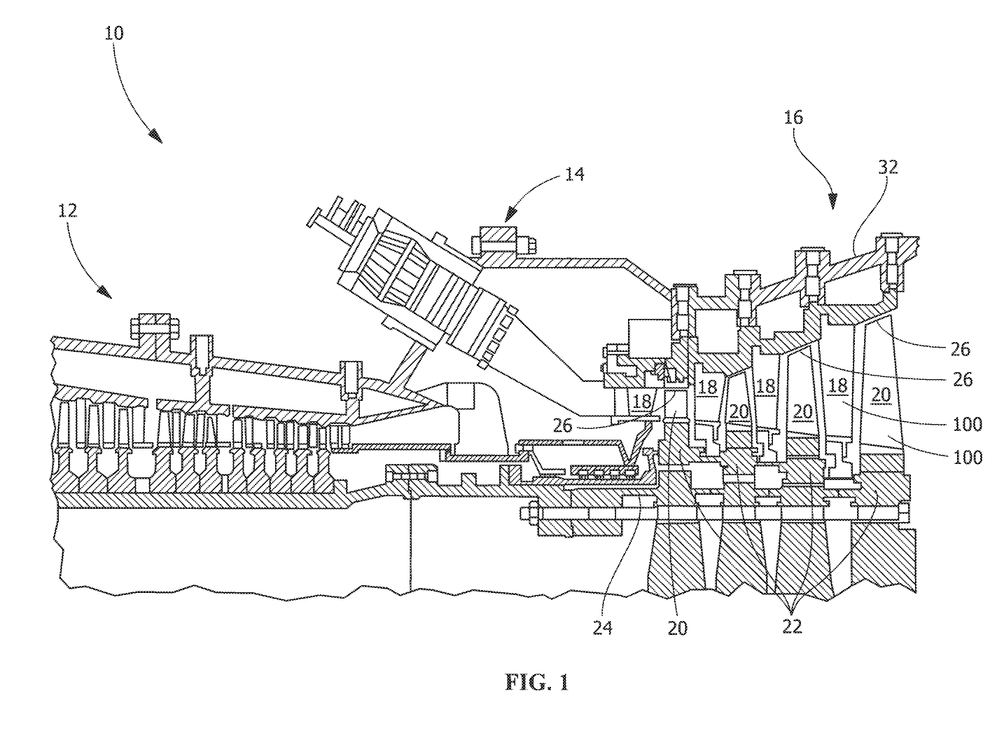

FIG. 1 shows an example of a power generation system 10, a gas turbine engine, having a compressor section 12, a combustor section 14 and a turbine section 16. In turbine section 16, there are alternating rows of stationary airfoils or vanes 18 and rotating airfoils or blades 20. Each row of blades 20 is formed by a plurality of airfoils 20 attached to a disc 22 provided on a rotor 24. Blades 20 can extend radially outward from discs 22 and terminate in a region known as a blade tip 26. Each row of vanes 18 is formed by attaching plurality of vanes 18 to a vane carrier. Vanes 18 can extend radially inward from the inner peripheral surface of vane carrier 28. Vane carrier 28 is attached to an outer casing 32, which encloses turbine section 16 of engine 10. During operation of power generation system 10, high temperature and high velocity gases flow through rows of vanes 18 and blades 20 in turbine section 16.

The disclosure is a compositional coating system that provides protection of an environmental barrier coating (EBC) applied to a substrate, e.g., a gas turbine blade 20, made of ceramic matrix composites (CMC). The EBC coating includes a multilayered structure, protecting the underlying CMC by preventing attacks by environmental objects such as hot gas, foreign object damage (FOD), domestic object damages (DOD), water vapor and dry or wet oxygen. In the conventional EBC systems, the Si-based bond coat between the substrate and protective layers creeps during operations at elevated temperatures due to growth of thermally grown oxide (TGO) layers. A calculated thin film deposition at strategic places on the top layer of cracked EBC is disclosed. In the novel structured coating system the nano-coating of silicon metal (Si) may be deposited by directional epitaxy, advanced plasma source (APS) deposition, chemical vapor deposition (CVD), electron beam physical vapor deposition (EBPVD), or slurry method at strategic places, e.g., on the top layer where cracks form due to thermal mismatch. The thin film oxidizes to silicon dioxide or silica with the passage of time, thereby protecting the top layer by preventing the encroachment of moisture and wet oxygen.

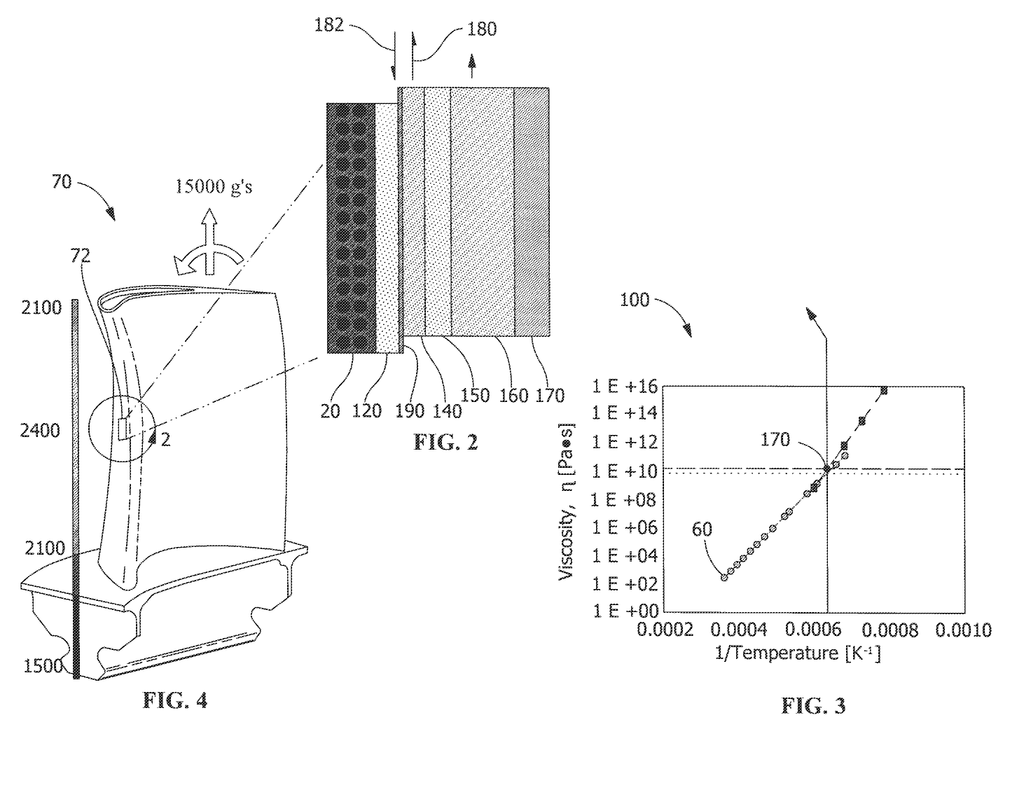

Referring next to FIG. 2, a creep mechanism of EBC 40 on a CMC substrate 20, e.g., a gas turbine bucket or blade, is shown. FIG. 2 illustrates an exemplary coating that may be applied to CMC substrate 20. Substrate 20 may be coated with bond layer 120 that may serve as a bond coat and assist in bonding the EBC layers to substrate 20. In an embodiment, bond layer 120 may be a silicon bond coat. EBC layer 140 may be applied on bond layer 120. Additional EBC layers 150, 160, and 170 may further be applied over EBC layer 140. Any number of EBC layers may be applied to substrate 20 and any other substrate or surface disclosed herein, using any means and methods, and any material may be used for any blade, bond layer, and EBC layer disclosed herein, including bond layer 120, EBC layers 140, 150, 160, and 170 and for blade 110. All such embodiments are contemplated as within the scope of the present disclosure.

In an exemplary embodiment, EBC layer 170 may be composed of, e.g., Y₂SiO₅, EBC layer 160 may be composed of, e.g., Y₂Si₂O₇ or Yb₂Si₂O₇, EBC layer 150 may be composed of, e.g., barium-strontium-aluminosilicate (BSAS), and EBC layer 140 may be composed of, e.g., e.g., Y₂Si₂O₇ or Yb2Si2O7. Arrows 180, 182 indicate shear forces acting on a TGO layer 190, e.g., SiO₂, which promotes creep. In an exemplary embodiment, the shear force during turbine operation may be 0.25 megapascals (MPa).

FIG. 3 provides a graph illustrating the rate of creep y as a function of viscosity η, in MPa, of TGO layer 190 versus inverse temperature scale (1/Temperature) in ° K⁻¹. Sampling points 60 range in viscosity from 1E+02 to 1E+16 pascal-seconds (Pa-s) viscosity and temperatures from 0.0002 K⁻¹ to 0.0010 K⁻¹. At intersection point 62 corresponding to about 0.0006 K⁻¹ and about 1E+10, γ is approximately equal to about 0.1 per hour, as calculated by Equation 1 below:

$$γ = \frac{τ}{η} \approx \frac{0.25 MPa}{{10}^{10 } Pa \cdot s} \approx 0.1 {hr}^{- 1} \qquad Eq . 1$$

FIG. 4 shows an exemplary turbine bucket 70 having a compositional bond coat represented in FIG. 2, as indicated by section 72. Turbine bucket 72 may be exposed to operational temperatures ranging from 1500° F. to 2100° F., and centrifugal and rotational forces up to 15000 gravitational forces (g's).

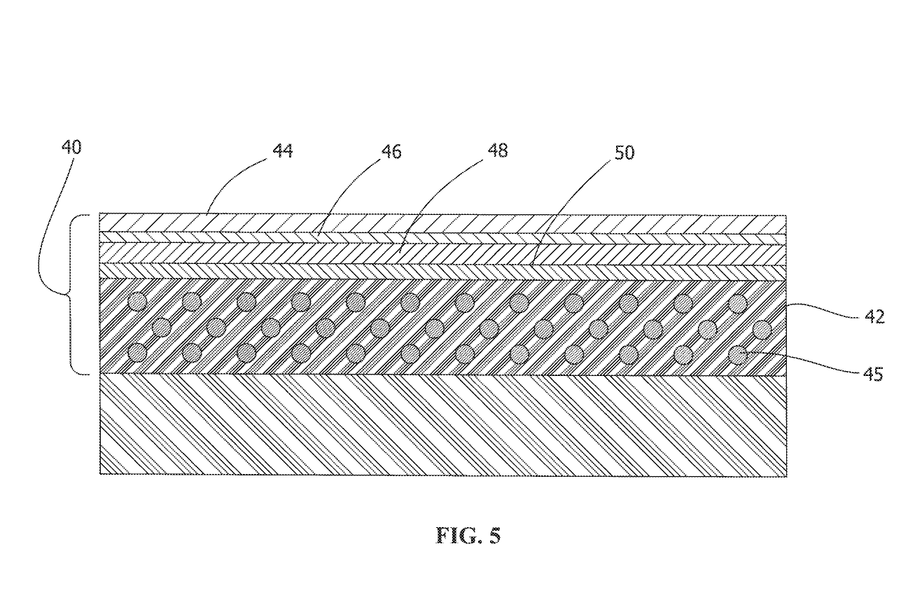

Referring next to FIG. 5, an EBC layer may be bonded to CMC substrate 20 via a Si-based bond coat 42. In the hot gas environment of, e.g., a gas turbine engine, Si-bond coat 42 oxidizes and melts due to elevated temperature, forming a thermally grown oxide (TGO) (not shown). The TGO is a viscous fluid layer which moves under shear stress originated from centrifugal load, and due to mismatch of co-efficient of thermal expansion (CTE) with the outer EBC layers 44, 46, 48, 50. In the exemplary embodiment there are four outer EBC layers 44, 46, 48, 50, although in other embodiments not more than two EBC layers may be used. The creep of EBC layer 40 may limit the life of a CMC turbine bucket 20, particularly when cracking of the outer protective layers occur. The application of silicon bond coat 42 prevents the encroachment of water vapor and oxygen species inside the outer cracked EBC layer, thereby prolonging the permeation of the species detailed here into the EBC matrix and consequently towards CMC blade 20. The epitaxial silicon thin film (100) is harder to oxidize than normally (110) deposited films. The thin layer oxidizes with the passage of time, preventing further oxidation of the blade by forming a protective oxide layer 40 between EBC layer and CMC substrate 20.

In one embodiment, first EBC layer 44 may be composed of, e.g., Y₂SiO₅, second EBC layer 46 may be composed of, e.g., Y₂Si₂O₇ or Yb₂Si₂O₇, third EBC layer 48 may be composed of, e.g., barium-strontium-aluminosilicate (BSAS), and fourth EBC layer 50 may be composed of, e.g., e.g., Y₂Si₂O₇ or Yb₂Si₂O₇.

The glass transition temperature T_{g}, which preferably is low, and glass melting temperature Tₘ, which is preferably high, may be used to evaluate the glass stability against crystallisation, in addition to parameters Weinburg and Hruby parameters K_{W} and K_{H}. Glass stability slightly increases when SiO₂ is the main glass former. Glass stability strongly decreases with the BaO content as the strongest glass modifier in the ternary system. Partial substitution of the alkaline earth (Ba²⁺, Ca²⁺) by Sr², characterized by a field strength z/a²=0.30) slightly decreased the glass stability. By contrast substitution of La⁵⁺ (z/a²=0.51) and Ce⁴⁺ (z/a²=0.078) in the silicon layer increases the Hruby parameter Ky. Without being bound by theory, increased field strength, as indicated by the Hruby parameter, reduces devitrification during thermal cycling.

It should be understood that the application is not limited to the details or methodology set forth in the following description or illustrated in the figures. It should also be understood that the phraseology and terminology employed herein is for the purpose of description only and should not be regarded as limiting.

While the exemplary embodiments illustrated in the figures and described herein are presently preferred, it should be understood that these embodiments are offered by way of example only. Accordingly, the present application is not limited to a particular embodiment, but extends to various modifications that nevertheless fall within the scope of the appended claims. The order or sequence of any processes or method steps may be varied or re-sequenced according to alternative embodiments.

It should be noted that although the figures herein may show a specific order of method steps, it is understood that the order of these steps may differ from what is depicted. Also two or more steps may be performed concurrently or with partial concurrence. Such variation will depend on the software and hardware systems chosen and on designer choice. It is understood that all such variations are within the scope of the application. Likewise, software implementations could be accomplished with standard programming techniques with rule based logic and other logic to accomplish the various connection steps, processing steps, comparison steps and decision steps.

1. A coating system for a gas turbine component comprising:
a bond layer applied to a substrate comprised of a ceramic matrix composite material; and
at least one environmental barrier coating (EBC) layer;
wherein the at least one EBC layer is bonded to the substrate by the bond layer;
wherein the bond layer comprises silicon and particles consisting of particles of Lanthanum or Cerium.

2. The coating system of claim 1, wherein the at least one EBC coating layer comprises a plurality of EBC coating layers.

3. The coating system of claim 2, wherein the at least one EBC layer comprises a plurality of EBC layers, comprising a first EBC layer comprising Y₂Si₂O₇.

4. The coating system of claim 2, wherein the at least one EBC layer comprises a plurality of EBC layers comprising a first EBC layer comprising Yb₂Si₂O₇.

5. The coating system of claim 3, further comprising a second EBC layer composed of barium-strontium-aluminosilicate.

6. The coating system of claim 4, further comprising a second EBC layer composed of barium-strontium-aluminosilicate.

7. The coating system of claim 5, further comprising a third EBC layer comprising Y₂Si₂O₇.

8. The coating system of claim 5, further comprising a third EBC layer comprising Yb₂Si₂O₇.

9. The coating system of claim 7 further comprising a fourth EBC layer comprising Y₂SiO₅.

10. The coating system of claim 8, further comprising a fourth EBC layer comprising Y₂SiO₅.

11. A method for protecting an environmental barrier coating (EBC) applied to a ceramic matrix composite (CMC) substrate of a turbine engine component, comprising:
providing at least one EBC layer, a CMC substrate and a Si-based bond coat;
bonding the at least one EBC layer to the CMC substrate via the bond coat;
exposing the component to elevated temperature;
oxidizing the Si-based bond coat and melting the Si-based bond coat when the component is exposed to the elevated temperature;
forming a thermally grown oxide (TGO) as a viscous fluid layer which moves under shear stress originated by a centrifugal load applied to the component;
preventing encroachment of water vapor and oxygen species inside an outer-most cracked EBC layer; and
prolonging the permeation of the water vapor and oxygen species into the at least one EBC layer and towards CMC substrate.

12. The method of claim 11, further comprising partially substituting an alkaline earth component by La5+ to increase the Hrubÿ parameter in the bond coat.

13. The method of claim 12, wherein the field strength is characterized by (z/a2=0.51).

14. The method of claim 11, further comprising partially substituting an alkaline earth component by Ce4+ to increase the Hrubÿ parameter in the bond coat.

15. The method of claim 14, wherein the field strength is characterized by (z/a2=0.078).

16. The method of claim 11, further comprising partially substituting an alkaline earth component by La5+ and Ce4+ to increase the Hrubÿ parameter in the bond coat.

17. The method of claim 11, further comprising stabilizing the glassy phase during thermal cycles.

18. The method of claim 11, further comprising co-depositing the at least one EBC layer by a method selected from the group consisting of: directional epitaxy, atmospheric plasma spraying (APS), chemical vapor deposition (CVD), Electron Beam Physical Vapor Deposition (EBPVD) or slurry methods.

19. The method of claim 11, further comprising wherein the bond coat comprises a directional silicon thin film, the directional silicon thin film having increased resistance to oxidization relative to non-directionally deposited films, wherein the bond coat layer oxidizes over time and prevents further oxidation of the CMC substrate by forming a protective oxide layer between the at least one EBC layer and the CMC substrate.

20. A coating for a gas turbine component comprising:
a substrate comprised of a ceramic matrix composite material;
a bond layer applied to the substrate, and at least one environmental barrier coating layer;
wherein the at least one environmental barrier coating layer is bonded to the substrate by the bond layer;
wherein the bond layer comprising silicon and particles consisting of particles of Lanthanum or Cerium;
wherein the at least one EBC coating layer comprises a plurality of EBC coating layers, wherein:
the at least one EBC layer comprising a plurality of EBC layers, comprising a first EBC layer comprising Y₂Si₂O₇ or Yb₂Si₂O₇, a second EBC layer composed of barium-strontium-aluminosilicate, a third EBC layer comprising Y₂Si₂O₇ or Yb₂Si₂O₇, and a fourth EBC layer comprising Y₂SiO₅.
